(19) United States
(12) Patent Application Publication
(10) Pub. No.: US 2025/0174511 A1
(43) Pub. Date: May 29, 2025

(54) METHOD FOR MANUFACTURING SUBSTRATE COOLING MECHANISM AND SUBSTRATE COOLING MECHANISM

(71) Applicants: NEC Corporation, Minato-ku, Tokyo (JP); NEC Platforms, Ltd., Kawasaki-shi, Kanagawa (JP)

(72) Inventors: Junichi Chiba, Kanagawa (JP); Yoshiki Kojima, Kanagawa (JP); Syouji Mori, Kanagawa (JP)

(73) Assignees: NEC Corporation, Minato-ku, Tokyo (JP); NEC Platforms, Ltd., Kawasaki-shi, Kanagawa (JP)

(21) Appl. No.: 18/843,347

(22) PCT Filed: Mar. 10, 2022
(86) PCT No.: PCT/JP2022/010738

§ 371 Date: Sep. 3, 2024

(51) Int. Cl. H01L 23/367; H01L 21/48; H01L 21/52; H01L 23/40

(52) U.S. Cl. CPC H01L 23/3675; H01L 21/4882; H01L 21/52; H01L 23/4012

(57) ABSTRACT

A method for manufacturing a substrate cooling mechanism, including: inserting a cooling plate from the opening part formed in a side surface of a housing and disposing the cooling plate on the lower-side substrate; having support members penetrate through through-holes of the cooling plate and fixing the rear-end of the support members to the lower-side substrate; arranging the upper-side substrate on the cooling plate and having the tip-end parts of the support members penetrate positioning through-holes of the upper-side substrate; and screwing a nut into a male screw thread of the tip-end parts of the support members so that the lower-side substrate and the upper-side substrate are brought closer with the cooling plate sandwiched therebetween and having the upper-side connector of the lower surface of the upper-side substrate and the lower-side connector of the upper surface of the lower-side substrate penetrate the through-holes formed in the cooling plate and mated.

### TECHNICAL FIELD

The present disclosure relates to a method for manufacturing a substrate cooling mechanism for cooling substrates and a substrate cooling mechanism.

### BACKGROUND ART

A substrate cooling mechanism in which substrates are respectively arranged on both sides (front and back surfaces) of a cooling plate is known (see, for example, Patent Literature 1).

### CITATION LIST

### Patent Literature

Patent Literature 1: Japanese Unexamined Patent Application Publication No. 2019-110245

### SUMMARY OF INVENTION

### Technical Problem

In the substrate cooling mechanism described above, it is necessary to fix the substrates to the upper-side and lower-side surfaces of a cooling plate. Therefore, an opening part needs to formed in a housing surrounding the substrates for performing fixing of the substrates to the upper-side and lower-side surfaces of the cooling plate, which may cause decrease in the strength of the housing.

An object of the present disclosure is to provide a method for manufacturing a substrate cooling mechanism and a substrate cooling mechanism which are adapted to solve any of the above-mentioned problems.

### Solution to Problem

An aspect of the present disclosure to achieve the above object is a method for manufacturing a substrate cooling mechanism, including:
a step of arranging a lower-side substrate on a bottom surface of a housing having an opening part formed in a side surface thereof, the lower-side substrate having a lower-side connector provided on an upper surface thereof;
a step of inserting a cooling plate from the opening part formed in a side surface of the housing and disposing the cooling plate on the lower-side substrate, the cooling plate having through-holes formed therein;
a step of having a plurality of support members penetrate the through-holes formed in the cooling plate, each of the plurality of the support members having a male screw thread formed at a tip-end part thereof, and fixing the rear-end of each of the support members to the lower-side substrate;
a step of positioning an upper-side substrate, the upper-side substrate having an upper-side connector formed on a lower surface of the upper-side substrate in which a plurality of positioning through-holes are formed, by arranging the upper-side substrate on the cooling plate and having the tip-end parts of the support members penetrate the positioning through-holes formed in the upper-side substrate; and
a step of screwing a nut into a male screw thread of each of the tip-end parts of the support members so that the lower-side substrate and the upper-side substrate are brought closer to each other with the cooling plate sandwiched therebetween and having the upper-side connector and the lower-side connector penetrate the through-holes formed in the cooling plate and mated.

Another aspect of the present disclosure to achieve the above object is a substrate cooling mechanism, including:
a housing having an opening part formed in a side surface thereof;
a lower-side substrate having a lower-side connector provided on an upper surface thereof and arranged on a bottom surface side of the housing;
a plurality of support members disposed on the lower-side substrate, each of the support members having a male screw thread formed at a tip-end part thereof;
a cooling plate having through-holes formed therein, the cooling plate being inserted from an opening part of the housing and disposed on the lower-side substrate; and
an upper-side substrate arranged on the cooling plate, the upper-side substrate having a plurality of positioning through-holes formed therein and having an upper-side connector provided on the lower surface of the upper-side substrate, wherein
the support members penetrate the cooling plate, the tip-end parts of the support members penetrating the positioning through-holes formed in the upper-side substrate, and by screwing a nut into a male screw thread of each of the tip-end parts, the lower-side substrate and the upper-side substrate are brought closer to each other with the cooling plate sandwiched therebetween, and the upper-side connector and the lower-side connector penetrate the through-holes formed in the cooling plate and are mated.

### Advantageous Effects of Invention

According to the present disclosure, it is possible to provide a method for manufacturing a substrate cooling mechanism and a substrate cooling mechanism which are adapted to solve any of the above-mentioned problems.

### BRIEF DESCRIPTION OF DRAWINGS

FIG. 1 is a diagram showing a schematic configuration of a substrate cooling mechanism according to an example embodiment;

FIG. 2 is a diagram showing through-holes formed in a cooling plate;

FIG. 3 is a diagram showing a state where an upper-side substrate is arranged on a cooling plate; and

FIG. 4 is a flowchart showing a flow of a method for manufacturing a substrate cooling mechanism according to an example embodiment.

### EXAMPLE EMBODIMENT

Hereinafter, example embodiments of the present disclosure will be described with reference to the drawings. However, the present disclosure is not limited to the following example embodiments. Moreover, not all of the configurations described in the embodiments are essential as means for solving the problem.

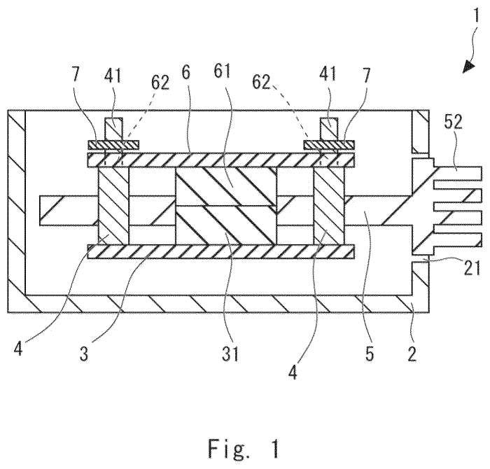

FIG. 1 is a diagram showing a schematic configuration of a substrate cooling mechanism according to an example embodiment. A substrate cooling mechanism 1 according to an example embodiment includes a housing 2, a lower-side substrate 3 disposed on the bottom surface side of the housing 2, a plurality of support members 4 disposed on the lower-side substrate 3, a cooling plate 5 disposed on the lower-side substrate 3, and an upper-side substrate 6 disposed on the cooling plate 5.

The housing 2 is, for example, a box-like member made of metal, and has an open upper surface. One roughly rectangular opening part 21 is formed in one side surface of the housing 2. A plurality of electronic components such as semiconductors are arranged on the lower-side substrate 3. A lower-side connector 31 is provided on the upper surface of the lower-side substrate 3.

The support member 4 is, for example, a bar-shaped member made of metal. The support member 4 has a male screw thread formed at a tip-end part 41 thereof. The support member 4 is fixed to the lower-side substrate 3. For example, the support member 4 is fixed to the lower-side substrate 3 by screwing the male screw thread formed at the rear-end of the support member 4 to a female screw thread formed on the lower-side substrate 3.

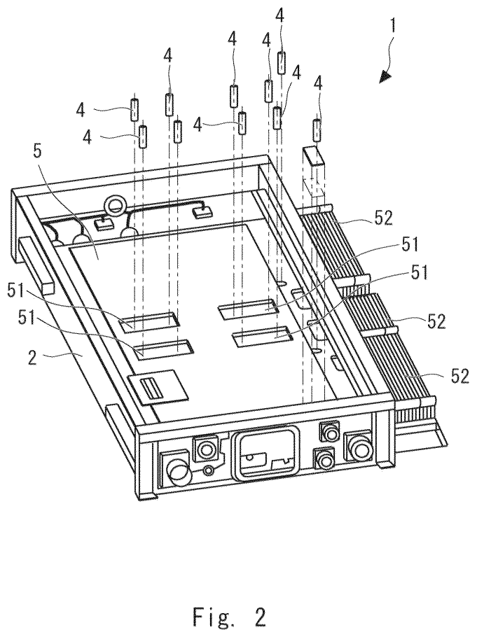

In the present example embodiment, for example, as shown in FIG. 2, ten support members 4 are disposed on the lower-side substrate 3, but the number of the support members are not limited thereto. The number of the support members 4 disposed on the lower-side substrate 3 may be any number as long as the upper-side substrate 6 is properly supported with respect to the lower-side substrate 3.

As shown in FIG. 1, the upper-side substrate 6 and the lower-side substrate 3 are respectively arranged on the upper-side and lower-side surfaces of the cooling plate 5, and the cooling plate 5 can simultaneously cool the upper-side substrate 6 and the lower-side substrate 3, thus having excellent cooling efficiency. The cooling plate 5 is inserted from the opening part 21 of the housing 2 and arranged on the lower-side substrate 3.

As shown in FIG. 2, through-holes 51 for penetrating the support member 4, the lower-side connector 31, and an upper-side connector 61 are formed in the cooling plate 5. Four roughly rectangular through-holes 51 are formed in the cooling plate 5, but the number of the through-holes are not limited thereto. The number and the shape of the through-holes 51 may be any number as long as the through-holes are configured such that the support member 4, the lower-side connector 31, and the upper-side connector 61 can penetrate the through-holes.

A cooling fin 52 for heat dissipation is provided on the side edge of the cooling plate 5. When the cooling plate 5 is inserted from the opening part 21 of the housing 2, the cooling fin 52 protrudes from the opening part 21 to the outside of the housing 2, and heat inside the housing 2 can be dissipated to the outside of the housing 2.

A plurality of electronic components such as semiconductors are arranged on the upper-side substrate 6. As shown in FIG. 1, the upper-side connector 61 is provided on the lower surface of the upper-side substrate 6. A plurality of positioning through-holes 62 for positioning the upper-side substrate 6 via the support members 4 are formed in the upper-side substrate 6. The positioning through-holes 62 are formed in the upper-side substrate 6, corresponding to the position of the support members 4.

The support members 4 penetrate the cooling plate 5, and the tip-end parts 41 of the support members 4 penetrate the positioning through-holes 62 formed in the upper-side substrate 6. At this time, the upper-side substrate 6 is positioned relative to the lower-side substrate 3 via the support members 4. Then, by screwing the nuts 7 into a male screw thread formed at each of the tip-end parts 41 of the respective support members 4, the lower-side substrate 3 and the upper-side substrate 6 are brought closer to each other with the cooling plate 5 sandwiched therebetween.

As a result, the upper-side connector 61 and the lower-side connector 31 penetrate the through-holes 51 formed in the cooling plate 5 and are mated. Due to the aforementioned mating, the upper-side connector 61 and the lower-side connector 31 are electrically connected, whereby the upper-side substrate 6 and the lower-side substrate 3 are electrically connected.

In the case of the substrate cooling mechanism in which the substrates are respectively arranged on the upper-side and lower-side surfaces of the cooling plate in the housing, in general, it is necessary to fix the substrates to the upper-side and lower-side surfaces of the cooling plate. Therefore, an opening part for performing fixing of the substrates to the upper-side and lower-side surfaces of the cooling plate is required in the housing surrounding the substrates, which may cause decrease in the strength of the housing.

In contrast, in the present example embodiment, as described above, the support members 4 fixed to the lower-side substrate 3 penetrate the cooling plate 5, the tip-end parts 41 of the respective support members 4 penetrating the corresponding positioning through-holes 62 formed in the upper-side substrate 6, and the nuts 7 are screwed into a male screw thread of each of the tip-end parts 41. As a result, the lower-side substrate 3 and the upper-side substrate 6 are brought closer to each other with the cooling plate 5 sandwiched therebetween, and the upper-side connector 61 and the lower-side connector 31 penetrate the through-holes 51 formed in the cooling plate 5 and are mated.

As described above, the upper-side substrate 6 and the lower-side substrate 3 can be fixed to the cooling plate 5 simultaneously by tightening the nuts 7 from one side of the cooling plate 5. Therefore, since only one opening part 21 corresponding to one side of the cooling plate 5 needs be provided in the side surface of the housing 2, decrease in the strength of the housing 2 can be suppressed. In addition, since the number of lids provided in the housing 2 can be reduced, a cost reduction effect can be expected due to the reduction in the number of parts.

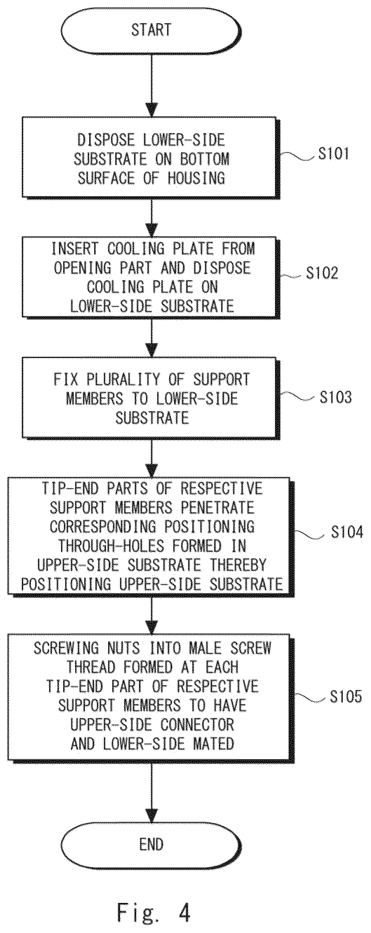

Next, a method for manufacturing the substrate cooling mechanism 1 according to an example embodiment will be described. FIG. 4 is a flowchart showing a flow of a method for manufacturing a substrate cooling mechanism according to an example embodiment.

First, the lower-side substrate 3 is disposed on the bottom surface of the housing 2 (Step S101).

Next, the cooling plate 5 is inserted from the opening part 21 provided in the side surface of the housing 2, and the cooling plate 5 is disposed on the lower-side substrate 3 (Step S102).

A plurality of the support members 4 are configured to respectively penetrate the through-holes 51 formed in the cooling plate 5, and the rear-end parts of the support members 4 are fixed to the lower-side substrate 3 (FIG. 2) (Step S103).

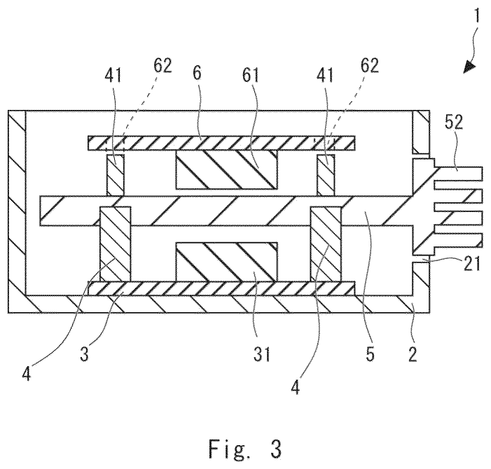

The upper-side substrate 6 is disposed on the cooling plate 5 (FIG. 3), and the tip-end parts 41 of the respective support members 4 are configured to penetrate the corresponding positioning through-holes 62 formed in the upper-side substrate 6, thereby positioning the upper-side substrate 6 (Step S104).

By screwing the nuts 7 into the male screw thread of each of the tip-end parts 41 of the respective support members 4, the lower-side substrate 3 and the upper-side substrate 6 are brought closer to each other with the cooling plate 5 sandwiched therebetween, and the upper-side connector 61 and the lower-side connector 31 penetrate the through-holes 51 formed in the cooling plate 5 and are mated (FIG. 1) (Step S105).

As described above, the substrate cooling mechanism 1 according to the present example embodiment includes: the housing 2 having the opening part 21 formed in the side surface thereof; the lower-side substrate 3 arranged on the bottom surface side of the housing 2, the lower-side substrate 3 having the lower-side connector 31 provided on the upper surface thereof; a plurality of the support members 4 arranged on the lower-side substrate 3, each support member having a male screw thread formed at the tip-end part 41 thereof; the cooling plate 5 inserted from the opening part 21 of the housing 2 and disposed on the lower-side substrate 3, the cooling plate 5 having the through-holes 51 formed therein; and the upper-side substrate 6 disposed on the cooling plate 5, the upper-side substrate 6 having a plurality of the positioning through-holes 62 formed therein and having the upper-side connector 61 formed on the lower surface thereof. The support members 4 penetrate the cooling plate 5, each of the tip-end parts 41 thereof penetrates a corresponding one of the positioning through-holes 62 formed in the upper-side substrate 6, and by screwing the nuts 7 into the male screw thread formed at each of the tip-end parts 41, the lower-side substrate 3 and the upper-side substrate 6 are brought closer to each other with the cooling plate 5 sandwiched therebetween, and the upper-side connector 61 and the lower-side connector 31 penetrate the through-holes 51 formed in the cooling plate 5 and are mated.

As described above, the upper-side substrate 6 and the lower-side substrate 3 can be simultaneously fixed to the cooling plate 5 by tightening the nuts 7 from one side of the cooling plate 5. Therefore, since one opening part 21 corresponding to one of the upper-side and lower-side surfaces of the cooling plate 5 is provided in the side surface of the housing 2, decrease in the strength of the housing 2 can be suppressed.

The substrate cooling mechanism 1 according to the example embodiments can be used, for example, for a cooling structure for cooling an electronic substrate used in a base station apparatus.

While several example embodiments of the present disclosure have been described, they are presented as examples and are not intended to limit the scope of present disclosure. These noble example embodiments can be implemented in a variety of other forms, and various omissions, replacements, and modifications can be made to the extent that they do not deviate from the gist of present disclosure. These and other variations are included in the scope and the gist of present disclosure and are equally within the scope of present disclosure described in the claims and the equivalents thereof.

### REFERENCE SIGNS LIST

1 SUBSTRATE COOLING MECHANISM
2 HOUSING
3 LOWER-SIDE SUBSTRATE
4 SUPPORT MEMBER
5 COOLING PLATE
6 UPPER-SIDE SUBSTRATE
7 NUT
21 OPENING PART
31 LOWER-SIDE CONNECTOR
41 TIP-END PART
51 THROUGH-HOLE
52 COOLING FIN
61 UPPER-SIDE CONNECTOR
62 POSITIONING THROUGH-HOLE

1. A method for manufacturing a substrate cooling mechanism, comprising:
a step of arranging a lower-side substrate on a bottom surface of a housing having an opening part formed in a side surface thereof, the lower-side substrate having a lower-side connector provided on an upper surface thereof;
a step of inserting a cooling plate from the opening part formed in a side surface of the housing and disposing the cooling plate on the lower-side substrate, the cooling plate having through-holes formed therein;
a step of having a plurality of support members penetrate the through-holes formed in the cooling plate, each of the plurality of the support members having a male screw thread formed at a tip-end part thereof, and fixing the rear-end of each of the support members to the lower-side substrate;
a step of positioning an upper-side substrate, the upper-side substrate having an upper-side connector formed on a lower surface of the upper-side substrate in which a plurality of positioning through-holes are formed, by arranging the upper-side substrate on the cooling plate and having the tip-end parts of the support members penetrate the positioning through-holes formed in the upper-side substrate; and
a step of screwing a nut into a male screw thread of each of the tip-end parts of the support members so that the lower-side substrate and the upper-side substrate are brought closer to each other with the cooling plate sandwiched therebetween and having the upper-side connector and the lower-side connector penetrate the through-holes formed in the cooling plate and mated.

2. A substrate cooling mechanism, comprising:
a housing having an opening part formed in a side surface thereof;
a lower-side substrate having a lower-side connector provided on an upper surface thereof and arranged on a bottom surface side of the housing;
a plurality of support members disposed on the lower-side substrate, each of the support members having a male screw thread formed at a tip-end part thereof;
a cooling plate having through-holes formed therein, the cooling plate being inserted from an opening part of the housing and disposed on the lower-side substrate; and
an upper-side substrate arranged on the cooling plate, the upper-side substrate having a plurality of positioning through-holes formed therein and having an upper-side connector provided on the lower surface of the upper-side substrate, wherein
the support members penetrate the cooling plate, the tip-end parts of the support members penetrating the positioning through-holes formed in the upper-side substrate, and by screwing a nut into a male screw thread of each of the tip-end parts, the lower-side substrate and the upper-side substrate are brought closer to each other with the cooling plate sandwiched therebetween, and the upper-side connector and the lower-side connector penetrate the through-holes formed in the cooling plate and are mated.
